(19) United States
(12) Patent Application Publication
(10) Pub. No.: US 2025/0017118 A1
(43) Pub. Date: Jan. 9, 2025

(54) MAGNETIC MEMORY DEVICE

(71) Applicant: Samsung Electronics Co., Ltd., Suwon-si (KR)

(72) Inventors: Se Chung Oh, Suwon-si (KR); JeongMok Kim, Suwon-si (KR); Tanyoung Kim, Suwon-si (KR); Heeju Shin, Suwon-si (KR); YoungJun Cho, Suwon-si (KR)

(21) Appl. No.: 18/412,778

(22) Filed: Jan. 15, 2024

(30) Foreign Application Priority Data
Jul. 6, 2023 (KR) 10-2023-0087695

(51) Int. Cl. H10N 50/80; H10B 61/00; H10N 50/01; H10N 50/20

(52) U.S. Cl. CPC H10N 50/80; H10B 61/00; H10N 50/01; H10N 50/20

(57) ABSTRACT

A magnetic memory device includes a reference magnetic pattern and a free magnetic pattern stacked on a substrate, a tunnel barrier pattern between the reference magnetic pattern and the free magnetic pattern, a first non-magnetic pattern on the free magnetic pattern, the free magnetic pattern being between the tunnel barrier pattern and the first non-magnetic pattern, a second non-magnetic pattern on the first non-magnetic pattern, the first non-magnetic pattern being between the free magnetic pattern and the second non-magnetic pattern, a metal pattern between the first non-magnetic pattern and the second non-magnetic pattern, and a conductive layer on a side surface of the first non-magnetic pattern.

### CROSS-REFERENCE TO RELATED APPLICATIONS

This U.S. non-provisional patent application claims priority under 35 U.S.C. § 119 to Korean Patent Application No. 10-2023-0087695, filed on Jul. 6, 2023, in the Korean Intellectual Property Office, the entire contents of which are hereby incorporated by reference.

### FIELD

The present disclosure relates to a magnetic memory device including a magnetic tunnel junction and a method of fabricating the same.

### BACKGROUND

As demand for electronic devices with increased speed and/or reduced power consumption increases, demand for semiconductor memory devices with faster operating speeds and/or lower operating voltages may increase. Due to their high speed operation and/or nonvolatility, magnetic memory devices are emerging as a promising alternative to traditional semiconductor memory devices.

In general, the magnetic memory device includes a magnetic tunnel junction (MTJ) pattern. The MTJ pattern includes two magnetic layers and an insulating layer interposed therebetween. Resistance of the MTJ pattern may vary depending on magnetization directions of the magnetic layers. For example, the electrical resistance of the MTJ pattern is higher when magnetization directions of the magnetic layers are anti-parallel to each other than when they are parallel to each other. Such a difference in electrical resistance can be used for data storing/reading operations of the magnetic memory device.

As the electronics industry advances, there may be increasing demand for optimization and/or low power consumption of the magnetic memory devices, and furthermore, studies are being conducted to improve the reliability of the magnetic memory device. For example, various research is being conducted to reduce or minimize the electrical shorts between magnetic elements in the magnetic tunnel junction pattern and to reduce the parasitic resistance of the magnetic tunnel junction pattern.

### SUMMARY

An embodiment of the inventive concept provides a magnetic memory device with improved electrical characteristics and a method of fabricating the same.

An embodiment of the inventive concept provides a magnetic memory device with improved reliability and a method of fabricating the same.

According to an embodiment of the inventive concept, a magnetic memory device may include a reference magnetic pattern and a free magnetic pattern stacked on a substrate, a tunnel barrier pattern between the reference magnetic pattern and the free magnetic pattern, a first non-magnetic pattern on the free magnetic pattern, the free magnetic pattern being between the tunnel barrier pattern and the first non-magnetic pattern, a second non-magnetic pattern on the first non-magnetic pattern, the first non-magnetic pattern being between the free magnetic pattern and the second non-magnetic pattern, a metal pattern between the first non-magnetic pattern and the second non-magnetic pattern, and a conductive layer on a side surface of the first non-magnetic pattern.

According to an embodiment of the inventive concept, a magnetic memory device may include a reference magnetic pattern and a free magnetic pattern stacked on a substrate, a tunnel barrier pattern between the reference magnetic pattern and the free magnetic pattern, an electrode spaced apart from the tunnel barrier pattern with the free magnetic pattern therebetween, a first non-magnetic pattern between the free magnetic pattern and the electrode, the first non-magnetic pattern including a first metal, a second non-magnetic pattern between the first non-magnetic pattern and the electrode, the second non-magnetic pattern including a second metal, a metal pattern between the first non-magnetic pattern and the second non-magnetic pattern, and a conductive layer on a side surface of the first non-magnetic pattern. An atomic mass of the first metal may be greater than or equal to an atomic mass of a metal element in the tunnel barrier pattern. The conductive layer may be spaced apart from a side surface of the tunnel barrier pattern.

### BRIEF DESCRIPTION OF THE DRAWINGS

FIG. 1 is a circuit diagram exemplarily illustrating a unit memory cell of a magnetic memory device according to an embodiment of the inventive concept.

FIGS. 2, 3, 4, and 5 are sectional views, each of which illustrates a magnetic memory device according to an embodiment of the inventive concept.

FIGS. 6 and 7 are sectional views illustrating a method of fabricating a magnetic memory device according to an embodiment of the inventive concept.

FIG. 8 is a plan view illustrating a magnetic memory device according to an embodiment of the inventive concept.

FIG. 9 is a sectional view taken along a line I-I′ of FIG. 8.

### DETAILED DESCRIPTION OF EMBODIMENTS

Example embodiments of the inventive concepts will now be described more fully with reference to the accompanying drawings, in which example embodiments are shown.

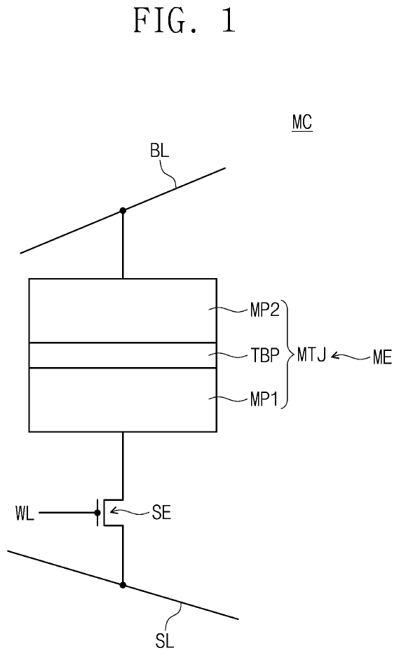

FIG. 1 is a circuit diagram exemplarily illustrating a unit memory cell of a magnetic memory device according to an embodiment of the inventive concept. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly on” or “in direct contact” or “directly connected,” no intervening components or layers are present.

Referring to FIG. 1, a unit memory cell MC may include a memory device ME and a selection element SE. The memory device ME and the selection element SE may be electrically connected to each other in series manner. The memory device ME may be provided between and connected to a bit line BL and the selection element SE. The selection element SE may be provided between and connected to the memory device ME and a source line SL and may be controlled by a word line WL. The selection element SE may include, for example, a bipolar transistor or a metal-oxide-semiconductor (MOS) field effect transistor.

The memory device ME may include a magnetic tunnel junction pattern MTJ, and the magnetic tunnel junction pattern MTJ may include a first magnetic structure MP1, a second magnetic structure MP2, and a tunnel barrier pattern TBP between the first and second magnetic structures MP1 and MP2. One of the first and second magnetic structures MP1 and MP2 may be a reference magnetic pattern, which has a fixed magnetization direction, regardless of the presence or absence of an external magnetic field generated under a typical usage environment. The other of the first and second magnetic structures MP1 and MP2 may be a free magnetic pattern, whose magnetization direction can be changed to one of two stable magnetization directions by an external magnetic field. The electrical resistance of the magnetic tunnel junction pattern MTJ may be much greater when magnetization directions of the reference and free magnetic patterns are antiparallel than when they are parallel. In other words, the electrical resistance of the magnetic tunnel junction pattern MTJ may be controlled by adjusting the magnetization direction of the free magnetic pattern. Thus, a difference in electrical resistance of the magnetic tunnel junction pattern MTJ, which is caused by a difference in magnetization direction between the reference and free magnetic patterns, may be used as a mechanism for storing data in the memory element ME or the unit memory cell MC.

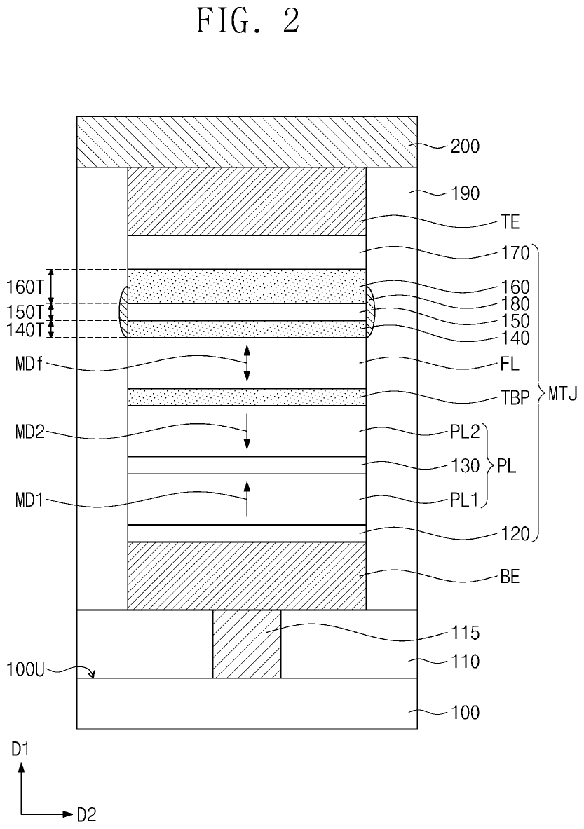

FIG. 2 is a sectional view illustrating a magnetic memory device according to an embodiment of the inventive concept.

Referring to FIG. 2, a first interlayer insulating layer 110 may be disposed on a substrate 100, and a lower contact plug 115 may be disposed in the first interlayer insulating layer 110. The substrate 100 may be a semiconductor substrate, which is formed of or includes at least one of silicon (Si), silicon germanium (SiGe), germanium (Ge), or gallium arsenide (GaAs), or may be a silicon-on-insulator (SOI) wafer. The first interlayer insulating layer 110 may be formed of or include at least one of silicon oxide, silicon nitride, and/or silicon oxynitride.

The lower contact plug 115 may be provided to penetrate the first interlayer insulating layer 110 and may be electrically connected to the substrate 100. A selection element (e.g., SE of FIG. 1) may be disposed in the substrate 100. In an embodiment, the selection element may be a field effect transistor. The lower contact plug 115 may be electrically connected to one of terminals (e.g., source/drain terminals) of the selection element. The lower contact plug 115 may be formed of or include at least one of doped semiconductor materials (e.g., doped silicon), metallic materials (e.g., tungsten, titanium, and/or tantalum), metal-semiconductor compounds (e.g., metal silicide), and conductive metal nitrides (e.g., titanium nitride, tantalum nitride, and/or tungsten nitride).

A bottom electrode BE, a magnetic tunnel junction pattern MTJ, and a top electrode TE may be sequentially stacked on the lower contact plug 115 in a first direction D1 that is perpendicular to a top surface 100U of the substrate 100. The bottom electrode BE may be disposed between the lower contact plug 115 and the magnetic tunnel junction pattern MTJ, and the magnetic tunnel junction pattern MTJ may be disposed between the bottom and top electrodes BE and TE. The bottom electrode BE may be electrically connected to the lower contact plug 115. The bottom electrode BE may be formed of or include at least one of conductive metal nitrides (e.g., titanium nitride or tantalum nitride). The top electrode TE may be formed of or include at least one of metallic materials (e.g., Ta, W, Ru, and Ir) or conductive metal nitrides (e.g., TiN).

The magnetic tunnel junction pattern MTJ may include a reference magnetic pattern PL, a free magnetic pattern FL, and a tunnel barrier pattern TBP between the reference magnetic pattern PL and the free magnetic pattern FL. In some embodiments, the reference magnetic pattern PL may be disposed between the bottom electrode BE and the tunnel barrier pattern TBP, and the free magnetic pattern FL may be disposed between the top electrode TE and the tunnel barrier pattern TBP. In this case, the bottom electrode BE may be referred to as a first electrode, and the top electrode TE may be referred to as a second electrode.

The reference magnetic pattern PL may include a first pinning pattern PL1, a second pinning pattern PL2 between the first pinning pattern PL1 and the tunnel barrier pattern TBP, and an exchange coupling pattern 130 between the first pinning pattern PL1 and the second pinning pattern PL2. In an embodiment, one of the first and second pinning patterns PL1 and PL2 may be used as a pinned pattern, and the other may be used as a pinning pattern. A magnetization direction MD1 of the first pinning pattern PL1 and a magnetization direction MD2 of the second pinning pattern PL2 may be perpendicular to an interface between the tunnel barrier pattern TBP and the free magnetic pattern FL. As an example, the magnetization direction MD1 of the first pinning pattern PL1 and the magnetization direction MD2 of the second pinning pattern PL2 may be perpendicular to the top surface 100U of the substrate 100. The first pinning pattern PL1 may be formed of or include at least one of iron (Fe), cobalt (Co), or nickel (Ni). The first pinning pattern PL1 may include at least one of perpendicular magnetic materials (e.g., CoFeTb, CoFeGd, and CoFeDy), perpendicular magnetic materials with L1₀ structure, CoPt-based materials with hexagonal-close-packed structure, and perpendicular magnetic structures. The perpendicular magnetic material with the L1₀ structure may include at least one of L1₀ FePt, L1₀ FePd, L1₀ CoPd, or L1₀ CoPt. The perpendicular magnetic structures may include magnetic and non-magnetic layers that are alternatingly and repeatedly stacked. As an example, the perpendicular magnetic structure may include at least one of (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ, or (CoCr/Pd)ₙ, where “n” is a natural number equal to or greater than 2. The second pinning pattern PL2 may be formed of or include at least one of iron (Fe), cobalt (Co), or nickel (Ni).

Due to the exchange coupling pattern 130, the first pinning pattern PL1 and the second pinning pattern PL2 may be antiferromagnetically coupled with each other. The exchange coupling pattern 130 may include a non-magnetic material with an antiferromagnetic coupling property. As an example, the exchange coupling pattern 130 may be formed of or include at least one of iridium (Ir) or ruthenium (Ru). The second pinning pattern PL2 may be antiferromagnetically coupled to the first pinning pattern PL1 by the exchange coupling pattern 130. In this case, the magnetization direction MD2 of the second pinning pattern PL2 may be anti-parallel to the magnetization direction MD1 of the first pinning pattern PL1.

The magnetic tunnel junction pattern MTJ may further include a seed pattern 120 between the bottom electrode BE and the reference magnetic pattern PL. The seed pattern 120 may include a material that facilitates or expedites the crystal growth of the reference magnetic pattern PL. For example, the seed pattern 120 may be formed of or include at least one of chromium (Cr), iridium (Ir), or ruthenium (Ru).

The tunnel barrier pattern TBP may include a metal oxide layer. The tunnel barrier pattern TBP may include at least one of, for example, magnesium oxide, titanium oxide, aluminum oxide, magnesium-zinc oxide, or magnesium-boron oxide.

The free magnetic pattern FL may have a perpendicular magnetization property, due to a magnetic anisotropy induced by the contact between the free magnetic pattern FL and the tunnel barrier pattern TBP. A magnetization direction MDf of the free magnetic pattern FL may be changed to be parallel or antiparallel to the magnetization direction MD2 of the second pinning pattern PL2. The free magnetic pattern FL may be formed of or include a magnetic material, which can induce the magnetic anisotropy at the interface between the free magnetic pattern FL and the tunnel barrier pattern TBP. In an embodiment, the free magnetic pattern FL may be formed of or include cobalt-iron-boron (CoFeB).

The magnetic tunnel junction pattern MTJ may further include a first non-magnetic pattern 140 between the free magnetic pattern FL and the top electrode TE, a second non-magnetic pattern 160 between the first non-magnetic pattern 140 and the top electrode TE, and a metal pattern 150 between the first and second non-magnetic patterns 140 and 160. The first non-magnetic pattern 140 may control the perpendicular magnetic anisotropy property of the free magnetic pattern FL. The perpendicular magnetic anisotropy property of the free magnetic pattern FL may be improved, due to a magnetic anisotropy that is induced at an interface between the first non-magnetic pattern 140 and the free magnetic pattern FL.

The first non-magnetic pattern 140 may include a first metal. An atomic mass of the first metal may be equal to or greater than an atomic mass of a metal element in the tunnel barrier pattern TBP. In some embodiments, the atomic mass of the first metal may be greater than the atomic mass of the metal element in the tunnel barrier pattern TBP. In the case where the metal element in the tunnel barrier pattern TBP is Mg, the first metal may be one of Hf, W, Mo, Ta, or Ir. The first non-magnetic pattern 140 may be formed of or include at least one of oxide or nitride materials containing the first metal. In the case where the tunnel barrier pattern TBP includes magnesium oxide (MgO), the first non-magnetic pattern 140 may be formed of or include at least one of metal oxide materials containing Hf, W, Mo, Ta, Ir, or alloys thereof, or metal nitride materials containing Hf, W, Mo, Ta, Ir, or alloys thereof. The first non-magnetic pattern 140 may further include boron (B). In some embodiments, the tunnel barrier pattern TBP may be formed of or include magnesium oxide (MgO), and the first non-magnetic pattern 140 may be formed of or include tantalum oxide (TaO) or tantalum boron oxide (TaBO).

The second non-magnetic pattern 160 may include a second metal. The second metal may be different from the first metal, and an atomic mass of the second metal may be different from an atomic mass of the first metal. In some embodiments, the atomic mass of the second metal may be greater than the atomic mass of the first metal. In the case where the first metal is tantalum (Ta), the second metal may be one of Ir, Pt, or Au. The second non-magnetic pattern 160 may be formed of or include at least one of oxide or nitride materials containing the second metal. In the case where the first non-magnetic pattern 140 includes tantalum oxide (TaO), the second non-magnetic pattern 160 may include at least one of metal oxide materials containing Ir, Pt, Au, or alloys thereof or metal nitride materials containing Ir, Pt, Au, or alloys thereof. The second non-magnetic pattern 160 may further include boron (B). In some embodiments, the first non-magnetic pattern 140 may be formed of or include tantalum oxide (TaO), and the second non-magnetic pattern 160 may be formed of or include at least one of iridium oxide (IrO) or iridium boron oxide (IrBO).

In some embodiments, a thickness 160T of the second non-magnetic pattern 160 in the first direction D1 may be larger than a thickness 140T of the first non-magnetic pattern 140 in the first direction D1.

The metal pattern 150 may include at least one of non-magnetic metal elements or ferromagnetic elements. The metal pattern 150 may be formed of or include at least one of the non-magnetic metal elements, the ferromagnetic elements, or alloys, which contain at least one of the elements. As an example, the metal pattern 150 may be formed of or include at least one of Ru, Ir, Pt, Co, Fe, Ni, or alloys thereof and may further include boron (B). In an embodiment, a thickness 150T of the metal pattern 150 in the first direction D1 may range from 3 Å to 30 Å. The first and second non-magnetic patterns 140 and 160 may be spaced apart from each other with the metal pattern 150 interposed therebetween. The metal pattern 150 may separate the first non-magnetic pattern 140 from the second non-magnetic pattern 160.

The magnetic tunnel junction pattern MTJ may further include a capping pattern 170 between the second non-magnetic pattern 160 and the top electrode TE. The capping pattern 170 may be used to prevent the deterioration of the free magnetic pattern FL, the first non-magnetic pattern 140, the metal pattern 150, and the second non-magnetic pattern 160. In an embodiment, the capping pattern 170 may be formed of or include at least one of tantalum (Ta), ruthenium (Ru), molybdenum (Mo), aluminum (Al), copper (Cu), gold (Au), silver (Ag), titanium (Ti), tantalum nitride (TaN), or titanium nitride (TiN).

A conductive layer 180 may cover at least a portion of a side surface of the magnetic tunnel junction pattern MTJ. The term “surround” or “cover” or “fill” or “enclose” as may be used herein may not require completely surrounding or covering or filling or enclosing the described elements or layers, but may, for example, refer to partially surrounding or covering or filling or enclosing the described elements or layers. The conductive layer 180 may cover a side surface of the first non-magnetic pattern 140 and may be extended to a region on a side surface of the metal pattern 150 and a side surface of the second non-magnetic pattern 160. The conductive layer 180 may be in contact with the side surface of the first non-magnetic pattern 140. The conductive layer 180 may be in contact with the side surface of the metal pattern 150 and may be in contact with at least a portion of the side surface of the second non-magnetic pattern 160. The conductive layer 180 may be spaced apart from a side surface of the tunnel barrier pattern TBP.

The conductive layer 180 may include the same material or element as at least one of the layers constituting the magnetic tunnel junction pattern MTJ. The conductive layer 180 may include the same material or element as at least one of the bottom and top electrodes BE and TE.

The magnetic tunnel junction pattern MTJ may be patterned using an ion beam etching process, and a conductive etch residue, which may be produced during the ion beam etching process, may be re-deposited on a side surface of the magnetic tunnel junction pattern MTJ. In the case where the conductive etch residue is re-deposited on a side surface of the tunnel barrier pattern TBP, an electrical short issue may occur between magnetic patterns in the magnetic tunnel junction pattern MTJ.

According to an embodiment of the inventive concept, the first non-magnetic pattern 140 may include the first metal that has an atomic mass greater than the metal element in the tunnel barrier pattern TBP. Thus, a binding energy between the material in the first non-magnetic pattern 140 and the conductive etch residue may be greater than a binding energy between the material in the tunnel barrier pattern TBP and the conductive etch residue. Due to this difference in binding energy between the first non-magnetic pattern 140 and the tunnel barrier pattern TBP in relation to the conductive etch residue, the conductive layer 180 may be formed on a side surface of the first non-magnetic pattern 140 and spaced apart from the side surface of the tunnel barrier pattern TBP. That is, the side surface or sidewall of the tunnel barrier pattern TBP may be free of the conductive etch residue or conductive layer 180 and may be separated therefrom. Since the conductive layer 180 is formed at a position spaced apart from the side surface of the tunnel barrier pattern TBP, it may prevent an electrical short issue from occurring between the magnetic patterns in the magnetic tunnel junction pattern MTJ.

In addition, the second non-magnetic pattern 160 may include the second metal that has an atomic mass greater than the first metal in the first non-magnetic pattern 140, and a thickness 160T of the second non-magnetic pattern 160 in the first direction D1 may be larger than a thickness 140T of the first non-magnetic pattern 140 in the first direction D1. Since the thickness 140T of the first non-magnetic pattern 140 is smaller than that of the second non-magnetic pattern 160, a binding energy between the material in the first non-magnetic pattern 140 and the conductive etch residue may be greater than a binding energy between the material in the second non-magnetic pattern 160 and the conductive etch residue. Thus, the conductive layer 180 may be more easily formed on (and, in some embodiments, may be formed in a greater amount on) a side surface of the first non-magnetic pattern 140 than on the side surface of the second non-magnetic pattern 160, and as a result, it may reduce a parasitic resistance issue caused by the first non-magnetic pattern 140.

As a result, in the magnetic memory device according to an embodiment of the inventive concept, it may be possible to prevent the electrical short issue between the magnetic patterns in the magnetic tunnel junction pattern MTJ and reduce a parasitic resistance issue in the magnetic tunnel junction pattern MTJ.

A second interlayer insulating layer 190 may be disposed on the first interlayer insulating layer 110 to cover side surfaces of the bottom electrode BE, the magnetic tunnel junction pattern MTJ, and the top electrode TE. The second interlayer insulating layer 190 may be formed of or include at least one of silicon oxide, silicon nitride, and/or silicon oxynitride.

An upper interconnection line 200 may be disposed on the second interlayer insulating layer 190 and may be connected to the top electrode TE. The upper interconnection line 200 may be extended in a second direction D2 parallel to the top surface 100U of the substrate 100. The upper interconnection line 200 may be electrically connected to the magnetic tunnel junction pattern MTJ through the top electrode TE and may be used as the bit line BL of FIG. 1. The upper interconnection line 200 may be formed of or include at least one of metallic materials (e.g., copper) or conductive metal nitride materials.

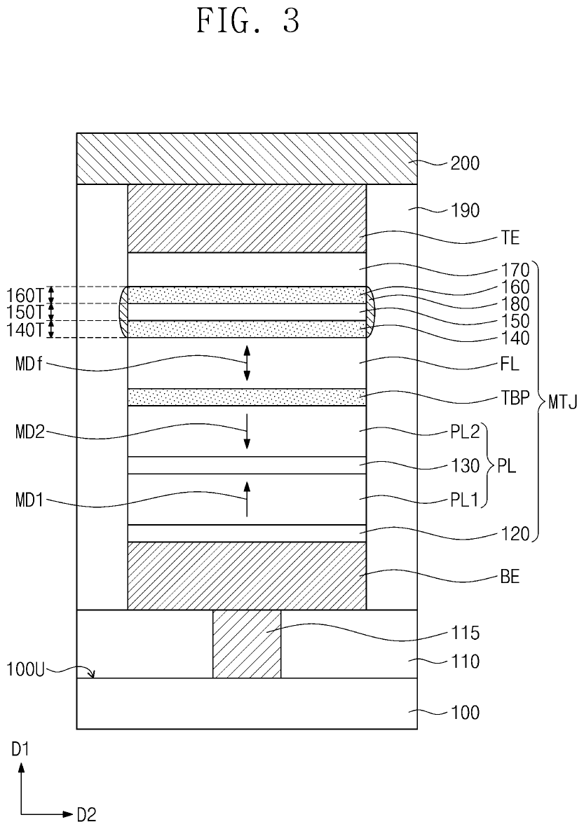

FIG. 3 is a sectional view illustrating a magnetic memory device according to an embodiment of the inventive concept. For the sake of brevity, elements, which are different from those in the magnetic memory device described with reference to FIG. 2, will be mainly described below.

Referring to FIG. 3, the second non-magnetic pattern 160 may include a second metal, and an atomic mass of the second metal may be less than an atomic mass of the first metal of the first non-magnetic pattern 140. In the case where the first metal is tantalum (Ta), the second metal may be one of Mg, Al, Ti, or Ru. The second non-magnetic pattern 160 may be formed of or include at least one of oxide or nitride materials containing the second metal. In the case where the first non-magnetic pattern 140 includes tantalum oxide (TaO), the second non-magnetic pattern 160 may include at least one of metal oxide materials containing Mg, Al, Ti, Ru, or alloys thereof or metal nitride materials containing Mg, Al, Ti, Ru, or alloys thereof. The second non-magnetic pattern 160 may further include boron (B). In some embodiments, the first non-magnetic pattern 140 may be formed of or include tantalum oxide (TaO), and the second non-magnetic pattern 160 may be formed of or include magnesium oxide (MgO) or magnesium boron oxide (MgBO).

In some embodiments, a thickness 160T of the second non-magnetic pattern 160 in the first direction D1 may be smaller than or equal to a thickness 140T of the first non-magnetic pattern 140 in the first direction D1.

According to an embodiment of the inventive concept, an atomic mass of the first metal of the first non-magnetic pattern 140 may be greater than an atomic mass of the metal element in the tunnel barrier pattern TBP and may be greater than an atomic mass of the second metal of the second non-magnetic pattern 160. Thus, a binding energy between the material in the first non-magnetic pattern 140 and the conductive etch residue may be greater than a binding energy between a material in the tunnel barrier pattern TBP and the conductive etch residue, and may be greater than a binding energy between a material in the second non-magnetic pattern 160 and the conductive etch residue. Due to these differences in binding energy between the first non-magnetic pattern 140 and the tunnel barrier pattern TBP and between the first and second non-magnetic patterns 140 and 160 in relation to the conductive etch residue, the conductive layer 180 may be more easily formed on a side surface of the first non-magnetic pattern 140 and may be spaced apart from the side surface of the tunnel barrier pattern TBP, such that the side surface of the tunnel barrier pattern TBP is free of the conductive layer 180 and is separated therefrom. Since the conductive layer 180 is formed at a position spaced apart from the side surface of the tunnel barrier pattern TBP, it may be possible to prevent an electrical short issue from occurring between magnetic patterns in the magnetic tunnel junction pattern MTJ. In addition, since the conductive layer 180 is more easily formed on the side surface of the first non-magnetic pattern 140, it may be possible to reduce a parasitic resistance issue caused by the first non-magnetic pattern 140.

In addition, the second non-magnetic pattern 160 may be formed to have a thickness 160T that is thinner than or equal to the first non-magnetic pattern 140, and in this case, it may be possible to reduce a parasitic resistance issue caused by the second non-magnetic pattern 160.

As a result, in the magnetic memory device according to an embodiment of the inventive concept, it may be possible to prevent the electrical short issue between the magnetic patterns in the magnetic tunnel junction pattern MTJ and reduce a parasitic resistance issue in the magnetic tunnel junction pattern MTJ.

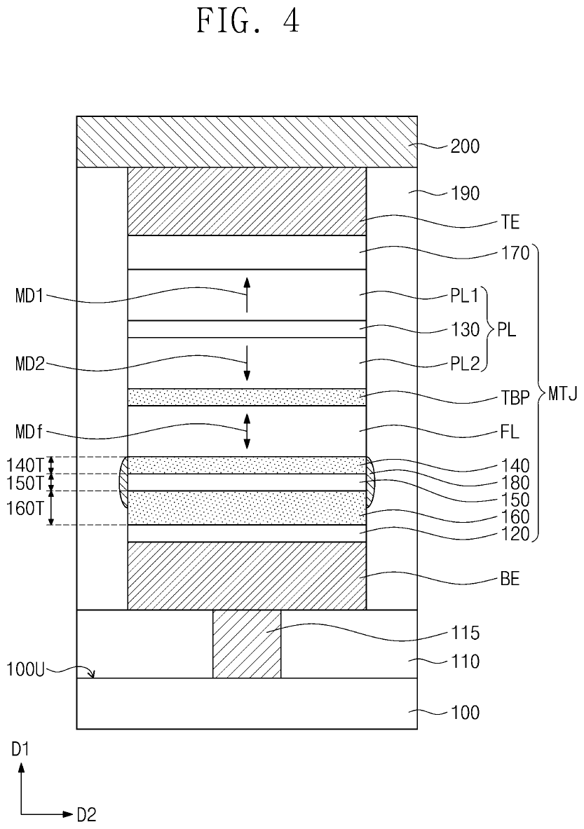

FIG. 4 is a sectional view illustrating a magnetic memory device according to an embodiment of the inventive concept. For the sake of brevity, elements, which are different from those in the magnetic memory device described with reference to FIG. 2, will be mainly described below.

Referring to FIG. 4, the free magnetic pattern FL may be disposed between the bottom electrode BE and the tunnel barrier pattern TBP, and the reference magnetic pattern PL may be disposed between the top electrode TE and the tunnel barrier pattern TBP. In this case, the top electrode TE may be referred to as a first electrode, and the bottom electrode BE may be referred to as a second electrode.

The reference magnetic pattern PL may include the first pinning pattern PL1, the second pinning pattern PL2 between the first pinning pattern PL1 and the tunnel barrier pattern TBP, and the exchange coupling pattern 130 between the first pinning pattern PL1 and the second pinning pattern PL2. The second pinning pattern PL2 may be antiferromagnetically coupled to the first pinning pattern PL1 by the exchange coupling pattern 130, and as a result, the magnetization direction MD2 of the second pinning pattern PL2 may be antiparallel to the magnetization direction MD1 of the first pinning pattern PL1.

The capping pattern 170 may be disposed between the top electrode TE and the reference magnetic pattern PL and may be used to prevent the deterioration of the reference magnetic pattern PL.

The first non-magnetic pattern 140 may be disposed between the free magnetic pattern FL and the bottom electrode BE, and the second non-magnetic pattern 160 may be disposed between the first non-magnetic pattern 140 and the bottom electrode BE. The metal pattern 150 may be disposed between the first and second non-magnetic patterns 140 and 160.

The seed pattern 120 may be disposed between the second non-magnetic pattern 160 and the bottom electrode BE. In some embodiments, at least a portion of the seed pattern 120 may have an amorphous phase and may prevent a crystalline structure of the bottom electrode BE from being transferred to the layers (e.g., the first and second non-magnetic patterns 140, 160, the metal pattern 150, and the free magnetic pattern FL) placed or formed on the seed pattern 120.

The conductive layer 180 may cover a side surface of the first non-magnetic pattern 140 and may be extended to a region on a side surface of the metal pattern 150 and a side surface of the second non-magnetic pattern 160. The conductive layer 180 may be spaced apart from a side surface of the tunnel barrier pattern TBP, such that the side surface of the tunnel barrier pattern TBP is free of the conductive layer 180 and is separated therefrom.

The magnetic memory device according to the present embodiments may be substantially the same as the magnetic memory device described with reference to FIG. 2, except for a difference in positions of the layers described above.

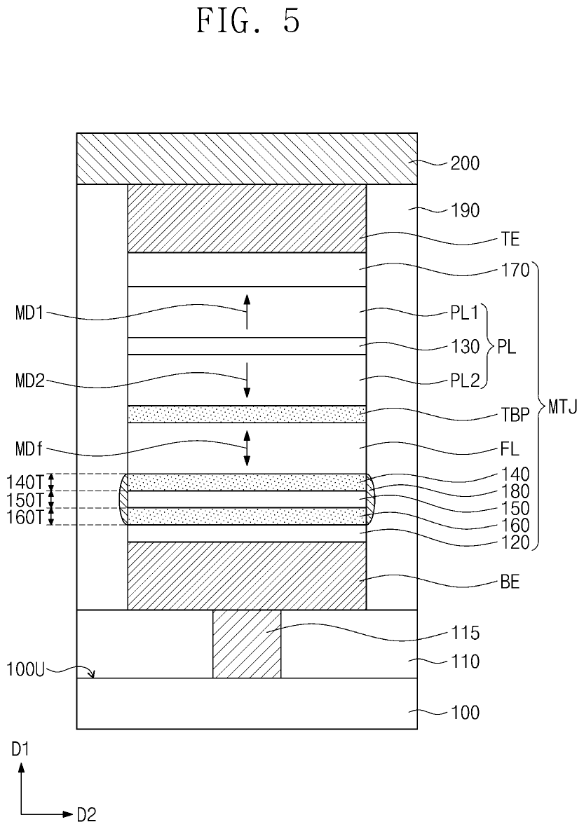

FIG. 5 is a sectional view illustrating a magnetic memory device according to an embodiment of the inventive concept. For the sake of brevity, elements, which are different from those in the magnetic memory device described with reference to FIG. 2, will be mainly described below.

Referring to FIG. 5, the free magnetic pattern FL may be disposed between the bottom electrode BE and the tunnel barrier pattern TBP, and the reference magnetic pattern PL may be disposed between the top electrode TE and the tunnel barrier pattern TBP. In this case, the top electrode TE may be referred to as a first electrode, and the bottom electrode BE may be referred to as a second electrode.

The reference magnetic pattern PL may include the first pinning pattern PL1, the second pinning pattern PL2 between the first pinning pattern PL1 and the tunnel barrier pattern TBP, and the exchange coupling pattern 130 between the first pinning pattern PL1 and the second pinning pattern PL2. The second pinning pattern PL2 may be antiferromagnetically coupled to the first pinning pattern PL1 by the exchange coupling pattern 130, and as a result, the magnetization direction MD2 of the second pinning pattern PL2 may be antiparallel to the magnetization direction MD1 of the first pinning pattern PL1.

The capping pattern 170 may be disposed between the top electrode TE and the reference magnetic pattern PL and may be used to prevent the deterioration of the reference magnetic pattern PL.

The first non-magnetic pattern 140 may be disposed between the free magnetic pattern FL and the bottom electrode BE, and the second non-magnetic pattern 160 may be disposed between the first non-magnetic pattern 140 and the bottom electrode BE. The metal pattern 150 may be disposed between the first and second non-magnetic patterns 140 and 160. In some embodiments, the second non-magnetic pattern 160 may include a second metal, and an atomic mass of the second metal may be less than an atomic mass of the first metal of the first non-magnetic pattern 140. A thickness 160T of the second non-magnetic pattern 160 in the first direction D1 may be smaller than or equal to a thickness 140T of the first non-magnetic pattern 140 in the first direction D1. The first and second non-magnetic patterns 140 and 160 may be provided to have substantially the same features as the first and second non-magnetic patterns 140 and 160 described with reference to FIG. 3.

The seed pattern 120 may be disposed between the second non-magnetic pattern 160 and the bottom electrode BE. In some embodiments, at least a portion of the seed pattern 120 may have an amorphous phase and may prevent a crystalline structure of the bottom electrode BE from being transferred to the layers (e.g., the first and second non-magnetic patterns 140, 160, the metal pattern 150, and the free magnetic pattern FL) placed or formed on the seed pattern 120.

The conductive layer 180 may cover a side surface of the first non-magnetic pattern 140 and may be extended to a region on a side surface of the metal pattern 150 and a side surface of the second non-magnetic pattern 160. The conductive layer 180 may be spaced apart from the side surface of the tunnel barrier pattern TBP.

Except for the afore-described differences, the magnetic memory device according to the present embodiments may be substantially the same as the magnetic memory device described with reference to FIG. 2.

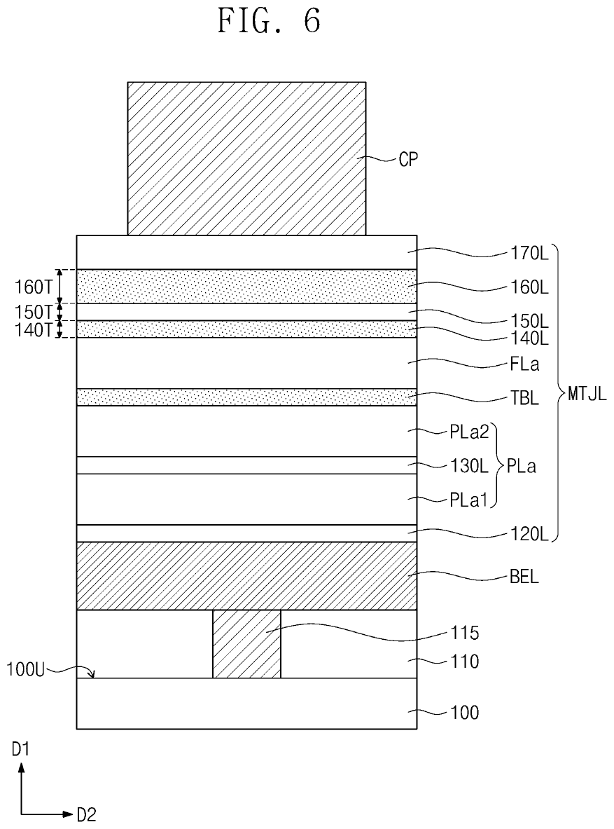

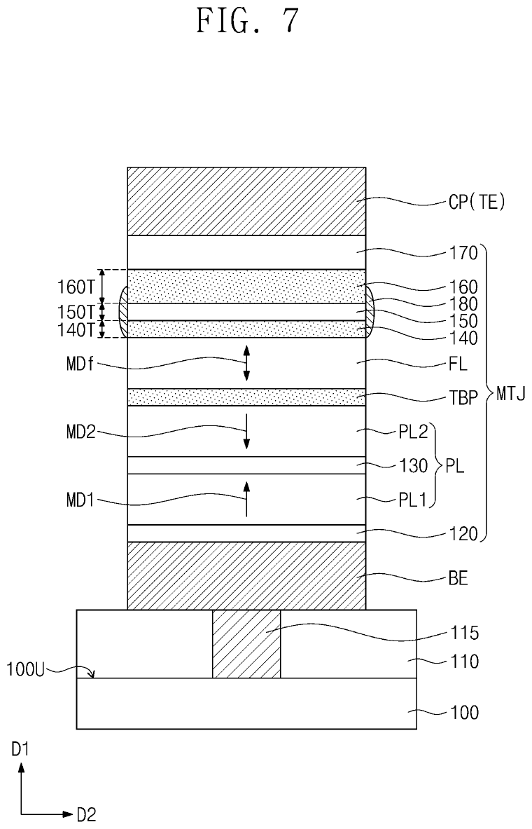

FIGS. 6 and 7 are sectional views illustrating a method of fabricating a magnetic memory device according to an embodiment of the inventive concept. For the sake of brevity, the same element as that in the magnetic memory device described with reference to FIGS. 2 to 5 may be identified by the same reference number without repeating an overlapping description.

Referring to FIG. 6, a first interlayer insulating layer 110 may be formed on a substrate 100, and a lower contact plug 115 may be formed in the first interlayer insulating layer 110. The lower contact plug 115 may be formed to penetrate the first interlayer insulating layer 110 and may be electrically connected to one of terminals (e.g., source/drain terminals) of a selection element (e.g., SE of FIG. 1) in the substrate 100.

A bottom electrode layer BEL, a seed layer 120L, a reference magnetic layer PLa, a tunnel barrier layer TBL, a free magnetic layer FLa, a first non-magnetic layer 140L, a metal layer 150L, a second non-magnetic layer 160L, and a capping layer 170L may be sequentially stacked on the first interlayer insulating layer 110. The reference magnetic layer PLa may include a first pinning layer PLa1, an exchange coupling layer 130L, and a second pinning layer PLa2, which are sequentially stacked on the seed layer 120L. The structure including the seed layer 120L, the reference magnetic layer PLa, the tunnel barrier layer TBL, the free magnetic layer FLa, the first non-magnetic layer 140L, the metal layer 150L, the second non-magnetic layer 160L, and the capping layer 170L may be referred to as a magnetic tunnel junction layer MTJL.

The tunnel barrier layer TBL may include a metal oxide material. The first non-magnetic layer 140L may include a first metal whose an atomic mass is greater than that of a metal element in the tunnel barrier layer TBL. The first non-magnetic layer 140L may be formed of or include at least one of oxide or nitride materials containing the first metal and may further include boron. The second non-magnetic layer 160L may be formed of or include a second metal different from the first metal. The second non-magnetic layer 160L may be formed of or include at least one of oxide or nitride materials containing the second metal and may further include boron. In some embodiments, an atomic mass of the second metal may be greater than an atomic mass of the first metal. In this case, a thickness 160T of the second non-magnetic layer 160L in the first direction D1 may be larger than a thickness 140T of the first non-magnetic layer 140L in the first direction D1. In other embodiments, as described with reference to FIG. 3, an atomic mass of the second metal may be smaller than an atomic mass of the first metal of the first non-magnetic pattern 140. In this case, a thickness 160T of the second non-magnetic layer 160L in the first direction D1 may be smaller than or equal to a thickness 140T of the first non-magnetic layer 140L in the first direction D1.

The metal layer 150L may include at least one of non-magnetic metal elements or ferromagnetic elements and may further include boron. In an embodiment, the metal layer 150L may be formed to have a thickness 150T ranging from 3 Å to 30 Å. The metal layer 150L may be interposed between the first non-magnetic layer 140L and the second non-magnetic layer 160L to separate the first non-magnetic layer 140L from the second non-magnetic layer 160L.

The bottom electrode layer BEL, the seed layer 120L, the reference magnetic layer PLa, the tunnel barrier layer TBL, the free magnetic layer FLa, the first non-magnetic layer 140L, the metal layer 150L, the second non-magnetic layer 160L, and the capping layer 170L may be formed by a chemical vapor deposition method or a physical vapor deposition method (e.g., a sputtering deposition method).

A conductive mask pattern CP may be formed on the capping layer 170L to define a region for a magnetic tunnel junction pattern, which will be described below. The conductive mask pattern CP may be formed of or include at least one of metallic materials (e.g., Ta, W, Ru, and Ir) or conductive metal nitride materials (e.g., TiN).

Referring to FIG. 7, the magnetic tunnel junction layer MTJL and the bottom electrode layer BEL may be sequentially etched by an etching process using the conductive mask pattern CP as an etch mask. In an embodiment, the etching process may be an ion beam etching process. A magnetic tunnel junction pattern MTJ and a bottom electrode BE may be respectively formed by the etching of the magnetic tunnel junction layer MTJL and the bottom electrode layer BEL.

The magnetic tunnel junction pattern MTJ may include a seed pattern 120, a reference magnetic pattern PL, a tunnel barrier pattern TBP, a free magnetic pattern FL, a first non-magnetic pattern 140, a metal pattern 150, a second non-magnetic pattern 160, and a capping pattern 170, which are formed by etching the seed layer 120L, the reference magnetic layer PLa, the tunnel barrier layer TBL, the free magnetic layer FLa, the first non-magnetic layer 140L, the metal layer 150L, the second non-magnetic layer 160L, and the capping layer 170L. The reference magnetic pattern PL may include a first pinning pattern PL1, an exchange coupling pattern 130, and a second pinning pattern PL2, which are respectively formed by etching the first pinning layer PLa1, the exchange coupling layer 130L, and the second pinning layer PLa2.

After the etching process, a remaining portion of the conductive mask pattern CP may be left on the magnetic tunnel junction pattern MTJ. The remaining portion of the conductive mask pattern CP may be referred to as a top electrode TE.

During the etching process, a conductive etch residue may be produced and may be re-deposited on a side surface of the magnetic tunnel junction pattern MTJ. According to an embodiment of the inventive concept, the first non-magnetic pattern 140 may include the first metal which has an atomic mass greater than the metal element in the tunnel barrier pattern TBP. Thus, a binding energy between the material in the first non-magnetic pattern 140 and the conductive etch residue may be greater than a binding energy between the material in the tunnel barrier pattern TBP and the conductive etch residue. Due to this difference in binding energy between the first non-magnetic pattern 140 and the tunnel barrier pattern TBP in relation to the conductive etch residue, a conductive layer 180 may be preferentially formed on a side surface of the first non-magnetic pattern 140 and at a position spaced apart from the side surface of the tunnel barrier pattern TBP. As such, the side surface or sidewall of the tunnel barrier pattern TBP may be free of the conductive etch residue or conductive layer 180 and may be separated therefrom.

In some embodiments, the second non-magnetic pattern 160 may include the second metal, which has an atomic mass greater than the first metal in the first non-magnetic pattern 140, and a thickness 160T of the second non-magnetic pattern 160 in the first direction D1 may be larger than a thickness 140T of the first non-magnetic pattern 140 in the first direction D1. Since the thickness 140T of the first non-magnetic pattern 140 is smaller than that of the second non-magnetic pattern 160, a binding energy between the material in the first non-magnetic pattern 140 and the conductive etch residue may be greater than a binding energy between the material in the second non-magnetic pattern 160 and the conductive etch residue. Thus, the conductive layer 180 may be more easily formed on the side surface of the first non-magnetic pattern 140 than on the side surface of the second non-magnetic pattern 160.

In other embodiments, the second non-magnetic pattern 160 may include the second metal, which has an atomic mass smaller than the first metal in the first non-magnetic pattern 140, and a thickness 160T of the second non-magnetic pattern 160 in the first direction D1 may be smaller than or equal to a thickness 140T of the first non-magnetic pattern 140 in the first direction D1. Here, an atomic mass of the first metal of the first non-magnetic pattern 140 may be greater than an atomic mass of the second metal of the second non-magnetic pattern 160, and in this case, a binding energy between the material in the first non-magnetic pattern 140 and the conductive etch residue may be greater than a binding energy between a material in the second non-magnetic pattern 160 and the conductive etch residue. Due to this difference in binding energy between the first and second non-magnetic patterns 140 and 160 in relation to the conductive etch residue, the conductive layer 180 may be more easily formed on a side surface of the first non-magnetic pattern 140 than on the side surface of the second non-magnetic pattern 160. In the case where the thickness 160T of the second non-magnetic pattern 160 is smaller than or equal to that of the first non-magnetic pattern 140, it may be possible to reduce a parasitic resistance issue caused by the second non-magnetic pattern 160.

Referring back to FIG. 2, a second interlayer insulating layer 190 may be formed on the first interlayer insulating layer 110 to cover the side surfaces of the bottom electrode BE, the magnetic tunnel junction pattern MTJ, and the top electrode TE. An upper interconnection line 200 may be formed on the second interlayer insulating layer 190 and may be connected to the top electrode TE. The upper interconnection line 200 may be a line-shaped pattern, which is extended in the second direction D2.

The magnetic memory devices described with reference to FIGS. 3 to 5 may be formed by the same method as the afore-described fabrication method.

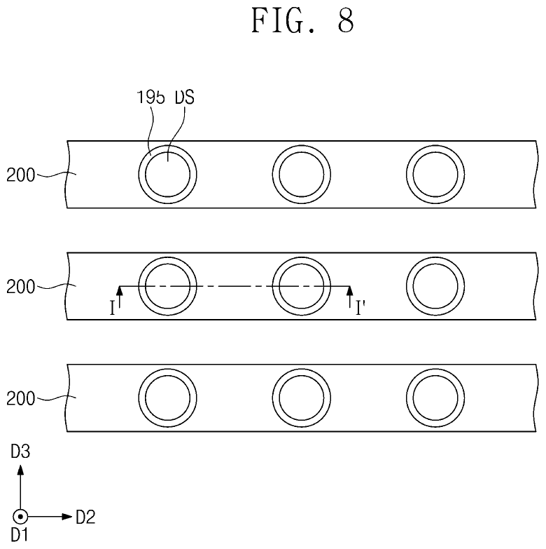

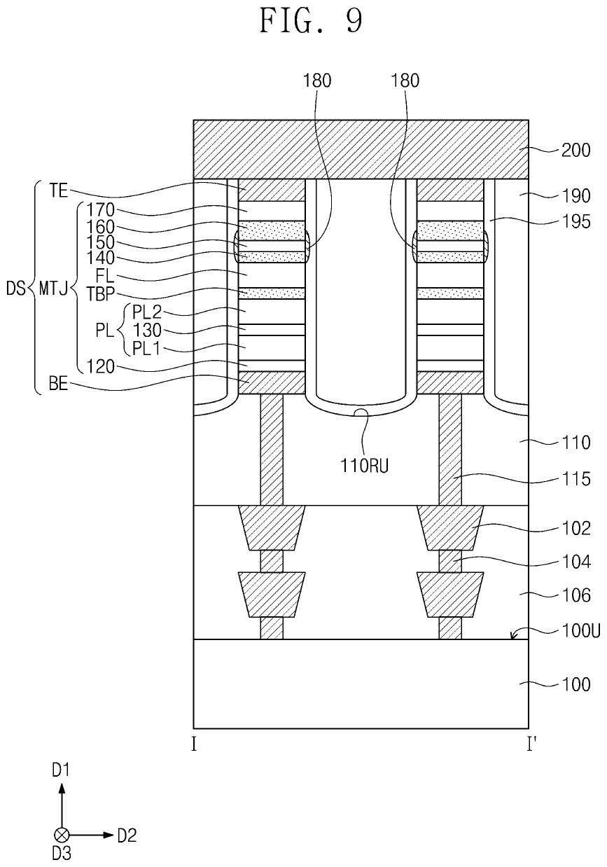

FIG. 8 is a plan view illustrating a magnetic memory device according to an embodiment of the inventive concept, and FIG. 9 is a sectional view taken along a line I-I′ of FIG. 8. For the sake of brevity, the same element as that in the magnetic memory device described with reference to FIGS. 2 to 5 may be identified by the same reference number without repeating an overlapping description.

Referring to FIGS. 8 and 9, interconnection lines 102 and interconnection contacts 104 may be disposed on a substrate 100. The interconnection lines 102 may be spaced apart from the top surface 100U of the substrate 100 in a first direction D1 that is perpendicular to the top surface 100U of the substrate 100. The interconnection contacts 104 may be disposed between the interconnection lines 102 and between the lowermost ones of the interconnection lines 102 and the substrate 100. Each of the interconnection lines 102 may be electrically connected to the substrate 100 through a corresponding one of the interconnection contacts 104. The interconnection lines 102 and the interconnection contacts 104 may be formed of or include at least one of metallic materials (e.g., copper).

Selection elements (e.g., SE of FIG. 1) may be disposed in the substrate 100. In an embodiment, the selection elements may be field effect transistors. Each of the interconnection lines 102 may be electrically connected to one of terminals (e.g., source/drain terminals) of a corresponding one of the selection elements through a corresponding one of the interconnection contacts 104.

An interconnection insulating layer 106 may be disposed on the substrate 100 to cover the interconnection lines 102 and the interconnection contacts 104. The interconnection insulating layer 106 may be formed to expose top surfaces of the uppermost ones of the interconnection lines 102. The top surfaces of the uppermost interconnection lines 102 may be coplanar with a top surface of the interconnection insulating layer 106. The top surfaces of the uppermost interconnection lines 102 may be located at substantially the same height as the top surface of the interconnection insulating layer 106. In the present specification, the term ‘height’ may mean a distance measured from the top surface 100U of the substrate 100 in the first direction D1. In an embodiment, the interconnection insulating layer 106 may be formed of or include silicon oxide, silicon nitride, and/or silicon oxynitride.

A first interlayer insulating layer 110 may be disposed on the interconnection insulating layer 106 to cover top surfaces of the uppermost interconnection lines 102.

A plurality of lower contact plugs 115 may be disposed in the first interlayer insulating layer 110. The lower contact plugs 115 may be spaced apart from each other in a second direction D2 and a third direction D3, which are parallel to the top surface 100U of the substrate 100. The second and third directions D2 and D3 may not be parallel to each other. Each of the lower contact plugs 115 may be provided to penetrate the first interlayer insulating layer 110 and may be connected to a corresponding one of the uppermost interconnection lines 102. The lower contact plugs 115 may be formed of or include at least one of doped semiconductor materials (e.g., doped silicon), metallic materials (e.g., tungsten, titanium, and/or tantalum), metal-semiconductor compounds (e.g., metal silicide), or conductive metal nitrides (e.g., titanium nitride, tantalum nitride, and/or tungsten nitride).

A plurality of data storage patterns DS may be disposed on the first interlayer insulating layer 110 and may be spaced apart from each other in the second and third directions D2 and D3. The data storage patterns DS may be disposed on and connected to the lower contact plugs 115, respectively.

Each of the data storage patterns DS may include a bottom electrode BE, a magnetic tunnel junction pattern MTJ, and a top electrode TE, which are sequentially stacked on a corresponding one of the lower contact plugs 115. The bottom electrode BE may be disposed between the corresponding lower contact plug 115 and the magnetic tunnel junction pattern MTJ, and the magnetic tunnel junction pattern MTJ may be disposed between the bottom and top electrodes BE and TE. The magnetic tunnel junction pattern MTJ may be configured to have the same features as the magnetic tunnel junction patterns MTJ described with reference to FIGS. 2 to 5.

A top surface of the first interlayer insulating layer 110 between the data storage patterns DS may be recessed toward the substrate 100. A protection insulating layer 195 may be provided to cover and enclose a side surface of each of the data storage patterns DS. The protection insulating layer 195 may cover the side surfaces of the bottom electrode BE, the magnetic tunnel junction pattern MTJ, and the top electrode TE and may enclose the side surfaces of the bottom electrode BE, the magnetic tunnel junction pattern MTJ, and the top electrode TE, when viewed in a plan view. The protection insulating layer 195 may cover the conductive layer 180 on the side surface of the magnetic tunnel junction pattern MTJ. The conductive layer 180 may be interposed between the side surface of the magnetic tunnel junction pattern MTJ and the protection insulating layer 195.

The protection insulating layer 195 may be extended from the side surface of each of the data storage patterns DS to a region on the recessed top surface 110RU of the first interlayer insulating layer 110. The protection insulating layer 195 may be conformally extended along the recessed top surface 110RU of the first interlayer insulating layer 110. The protection insulating layer 195 may be formed of or include at least one of nitride materials (e.g., silicon nitride).

A second interlayer insulating layer 190 may be disposed on the first interlayer insulating layer 110 to cover the data storage patterns DS. The protection insulating layer 195 may be interposed between the side surface of each of the data storage patterns DS and the second interlayer insulating layer 190 and may be extended into a region between the recessed top surface 110RU of the first interlayer insulating layer 110 and the second interlayer insulating layer 190.

A plurality of upper interconnection lines 200 may be disposed on the second interlayer insulating layer 190. The upper interconnection lines 200 may be extended in the second direction D2 and may be spaced apart from each other in the third direction D3. Each of the upper interconnection lines 200 may be (e.g., electrically) connected to ones of the data storage patterns DS, which are spaced apart from each other in the second direction D2.

According to an embodiment of the inventive concept, a first non-magnetic pattern may be provided to have a greater binding energy to a conductive etch residue that may be produced during an etching process for forming a magnetic tunnel junction pattern, compared with a tunnel barrier pattern. Thus, a conductive layer may be preferentially formed on a side surface of the first non-magnetic pattern and spaced apart from a side surface of the tunnel barrier pattern, such that the side surface of the tunnel barrier pattern is free of the conductive etch residue or layer and is separated therefrom. Since the conductive layer is formed on the side surface of the first non-magnetic pattern, a parasitic resistance issue caused by the first non-magnetic pattern may be reduced. In addition, since the conductive layer is formed at a position spaced apart from the side surface of the tunnel barrier pattern, an electrical short issue between magnetic patterns in the magnetic tunnel junction pattern may be prevented.

As a result, a magnetic memory device with improved electrical and reliability characteristics and a method of fabricating the same may be provided.

While example embodiments of the inventive concept have been particularly shown and described, it will be understood by one of ordinary skill in the art that variations in form and detail may be made therein without departing from the scope of the attached claims.

What is claimed is:

1. A magnetic memory device, comprising:
a reference magnetic pattern and a free magnetic pattern stacked on a substrate;
a tunnel barrier pattern between the reference magnetic pattern and the free magnetic pattern;
a first non-magnetic pattern on the free magnetic pattern, wherein the free magnetic pattern is between the tunnel barrier pattern and the first non-magnetic pattern;
a second non-magnetic pattern on the first non-magnetic pattern, wherein the first non-magnetic pattern is between the free magnetic pattern and the second non-magnetic pattern;
a metal pattern between the first non-magnetic pattern and the second non-magnetic pattern; and
a conductive layer on a side surface of the first non-magnetic pattern.

2. The magnetic memory device of claim 1, wherein the first non-magnetic pattern comprises an oxide material of a first metal or a nitride material of the first metal, and
an atomic mass of the first metal is greater than or equal to an atomic mass of a metal element in the tunnel barrier pattern.

3. The magnetic memory device of claim 2, wherein the second non-magnetic pattern comprises an oxide material of a second metal or a nitride material of the second metal, and
the second metal is different from the first metal.

4. The magnetic memory device of claim 3, wherein an atomic mass of the second metal is greater than the atomic mass of the first metal.

5. The magnetic memory device of claim 4, wherein a thickness of the second non-magnetic pattern in a first direction perpendicular to a top surface of the substrate is greater than a thickness of the first non-magnetic pattern in the first direction.

6. The magnetic memory device of claim 3, wherein an atomic mass of the second metal is less than the atomic mass of the first metal.

7. The magnetic memory device of claim 6, wherein a thickness of the second non-magnetic pattern in a first direction perpendicular to a top surface of the substrate is less than or equal to a thickness of the first non-magnetic pattern in the first direction.

8. The magnetic memory device of claim 1, wherein the metal pattern comprises a non-magnetic metal element, a ferromagnetic element, or an alloy comprising at least one of the non-magnetic metal element or the ferromagnetic element.

9. The magnetic memory device of claim 1, further comprising:
a first electrode spaced apart from the tunnel barrier pattern with the reference magnetic pattern therebetween; and
a second electrode spaced apart from the tunnel barrier pattern with the free magnetic pattern therebetween,
wherein the first non-magnetic pattern, the second non-magnetic pattern, and the metal pattern are between the free magnetic pattern and the second electrode, and
the conductive layer comprises a same material as at least one of the first electrode or the second electrode.

10. The magnetic memory device of claim 1, wherein the conductive layer extends from the side surface of the first non-magnetic pattern to a region on a side surface of the metal pattern, and wherein a side surface of the tunnel barrier pattern is free of the conductive layer.

11. The magnetic memory device of claim 10, wherein the conductive layer is further extends to a region on a side surface of the second non-magnetic pattern.

12. A magnetic memory device, comprising:
a reference magnetic pattern and a free magnetic pattern stacked on a substrate;
a tunnel barrier pattern between the reference magnetic pattern and the free magnetic pattern;
an electrode spaced apart from the tunnel barrier pattern with the free magnetic pattern therebetween;
a first non-magnetic pattern between the free magnetic pattern and the electrode, the first non-magnetic pattern comprising a first metal;
a second non-magnetic pattern between the first non-magnetic pattern and the electrode, the second non-magnetic pattern comprising a second metal;
a metal pattern between the first non-magnetic pattern and the second non-magnetic pattern; and
a conductive layer on a side surface of the first non-magnetic pattern,
wherein an atomic mass of the first metal is greater than or equal to an atomic mass of a metal element in the tunnel barrier pattern, and
the conductive layer is spaced apart from a side surface of the tunnel barrier pattern.

13. The magnetic memory device of claim 12, wherein the first non-magnetic pattern comprises an oxide material of the first metal or a nitride material of the first metal, and wherein the second non-magnetic pattern comprises an oxide material of the second metal or a nitride material of the second metal.

14. The magnetic memory device of claim 13, wherein the second metal is different from the first metal.

15. The magnetic memory device of claim 13, wherein an atomic mass of the second metal is greater than the atomic mass of the first metal.

16. The magnetic memory device of claim 15, wherein a thickness of the second non-magnetic pattern in a first direction perpendicular to a top surface of the substrate is greater than a thickness of the first non-magnetic pattern in the first direction.

17. The magnetic memory device of claim 13, wherein an atomic mass of the second metal is less than the atomic mass of the first metal.

18. The magnetic memory device of claim 12, wherein the conductive layer is in contact with the side surface of the first non-magnetic pattern.

19. The magnetic memory device of claim 12, wherein the metal pattern comprises a non-magnetic metal element, a ferromagnetic element, or an alloy comprising at least one of the non-magnetic metal element or the ferromagnetic element, and
the conductive layer extends from the side surface of the first non-magnetic pattern to a region on a side surface of the metal pattern.

20. A magnetic memory device, comprising:
a reference magnetic pattern and a free magnetic pattern stacked on a substrate;
a tunnel barrier pattern between the reference magnetic pattern and the free magnetic pattern;
an electrode spaced apart from the tunnel barrier pattern with one of the free magnetic pattern or the reference magnetic pattern therebetween;
a first non-magnetic pattern between the free magnetic pattern and the electrode;
a second non-magnetic pattern between the first non-magnetic pattern and the electrode;
a metal pattern between the first non-magnetic pattern and the second non-magnetic pattern,
wherein the first non-magnetic pattern comprises a first metal having a greater binding energy to a conductive material of the electrode than a second metal of the tunnel barrier pattern.
